(19) United States
(12) Patent Application Publication
(10) Pub. No.: US 2026/0096062 A1
(43) Pub. Date: Apr. 2, 2026

(54) BOARD-SIDE SPRING MOUNTING TO HEAT-REJECTING MEDIA

(71) Applicant: Dell Products L.P., Round Rock, TX (US)

(72) Inventors: Qinghong HE, Austin, TX (US); Jay M. ZILL, Round Rock, TX (US); Hao-Wu YANG, Taipei City (TW); Shi-Wei YANG, Taoyuan (TW)

(73) Assignee: Dell Products L.P., Round Rock, TX (US)

(21) Appl. No.: 18/901,677

(22) Filed: Sep. 30, 2024

(51) Int. Cl. H05K 7/20; G06F 1/20; H05K 1/02

(52) U.S. Cl. CPC H05K 7/2049; H05K 1/0204; G06F 1/203

(57) ABSTRACT

An information handling system may include a circuit board comprising an electronic device mechanically and electrically mounted on a first surface of the circuit board, a plurality of openings formed within a second surface of the circuit board opposite of the first surface, and a bracket mechanically mounted to the second surface, the bracket comprising a plurality of ends, each end extending into a respective opening of the plurality of openings, heat-rejecting media, and a plurality of mechanical fastening devices, each mechanical fastening device mechanically engaged with a respective first mechanical feature formed in a respective end of the plurality of ends and mechanically engaged with a respective second mechanical feature formed in the heat-rejecting media in order to apply a spring force between the bracket and the heat-rejecting media that applies mechanical pressure to thermally couple the electronic device to the heat-rejecting media.

### TECHNICAL FIELD

The present disclosure relates in general to information handling systems, and more particularly to cooling of information handling system components using one or more air movers, including the thermal coupling of a device to heat-rejecting media.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

As processors, graphics cards, random access memory (RAM) and other components in information handling systems have increased in clock speed and power consumption, the amount of heat produced by such components as a side-effect of normal operation has also increased. Often, the temperatures of these components need to be kept within a reasonable range to prevent overheating, instability, malfunction and damage leading to a shortened component lifespan. Accordingly, air movers (e.g., cooling fans and blowers) have often been used in information handling systems to cool information handling systems and their components.

Further, heat-rejecting media such as heat pipes, heat spreaders, and heat sinks are often thermally coupled to heat-generating devices of information handling systems and placed in the airflow path of an air mover, to also aid in cooling of an information handling system and its components. Such heat-rejecting media may be thermally-coupled to one or more heat—generating devices of an information handling system, and configured to transfer heat from such heat-generating devices. Further, such heat-rejecting media may include surfaces located within the airflow of air movers, so that heat may further be transferred from heat-rejecting media to the cooling airflow.

In traditional approaches in notebook computers (e.g., “laptops”), heat-rejecting media is often mounted to a circuit board (e.g., a circuit board having a processor, graphics processing unit, or other heat-generating device mounted thereon) with springs such as coil or leaf springs. Such approach works well when heat-rejecting media is closer to a bottom cover (e.g., “D-cover”) of a keyboard assembly and the circuit board is closer to a keyboard of the keyboard assembly. However, in more modern notebook computers, heat-rejecting media may be closer to the keyboard while the circuit board may be closer to the D-cover. Such a configuration presents challenges in terms of mounting the circuit board in a limited height of the keyboard assembly as traditional mounting using a spring, screw head, stiffener bracket and other components can have significant height.

### SUMMARY

In accordance with the teachings of the present disclosure, the disadvantages and problems associated with traditional approaches to cooling information handling system components may be substantially reduced or eliminated.

In accordance with embodiments of the present disclosure, an information handling system may include a circuit board comprising an electronic device mechanically and electrically mounted on a first surface of the circuit board, a plurality of openings formed within a second surface of the circuit board opposite of the first surface, and a bracket mechanically mounted to the second surface, the bracket comprising a plurality of ends, each end extending into a respective opening of the plurality of openings, heat-rejecting media, and a plurality of mechanical fastening devices, each mechanical fastening device mechanically engaged with a respective first mechanical feature formed in a respective end of the plurality of ends and mechanically engaged with a respective second mechanical feature formed in the heat-rejecting media in order to apply a spring force between the bracket and the heat-rejecting media that applies mechanical pressure to thermally couple the electronic device to the heat-rejecting media.

In accordance with these and other embodiments of the present disclosure, a method may include mechanically engaging each of a plurality of mechanical fastening devices with a respective first mechanical feature, and mechanically engaging each of the plurality of mechanical fastening devices with a respective second mechanical feature formed in the heat-rejecting media. Each of the first mechanical features may be formed in a respective end of a bracket mounted to a first surface of a circuit board and each of the first mechanical features extend into a respective opening of a plurality of openings formed within a first surface of the circuit board and the circuit board may include an electronic device mechanically and electrically mounted on a second surface of the circuit board opposite of the first surface, such that a spring force is applied between the bracket and the heat-rejecting media that applies mechanical pressure to thermally couple the electronic device to the heat-rejecting media.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of selected components of an example information handling system, in accordance with embodiments of the present disclosure;

FIG. 2 illustrates selected components of an example notebook, in accordance with embodiments of the present disclosure;

FIG. 3A illustrates an exploded isometric perspective view of selected components of the notebook depicted in FIG. 2, demonstrating a system and method for board-side mounting of a device to heat-rejecting media using a bracket with drop-down ends, in accordance with embodiments of the present disclosure;

FIG. 3B illustrates an assembled isometric perspective view of the selected components depicted in FIG. 3A, in accordance with embodiments of the present disclosure;

FIG. 3C illustrates an assembled cross-sectional elevation perspective view of the selected components depicted in FIGS. 3A and 3B, in accordance with embodiments of the present disclosure; and

FIG. 4 illustrates an assembled isometric perspective view of selected components of the notebook depicted in FIG. 2, demonstrating another system and method for board-side mounting of a device to heat-rejecting media using a bracket with drop-down ends, in accordance with embodiments of the present disclosure.

### DETAILED DESCRIPTION

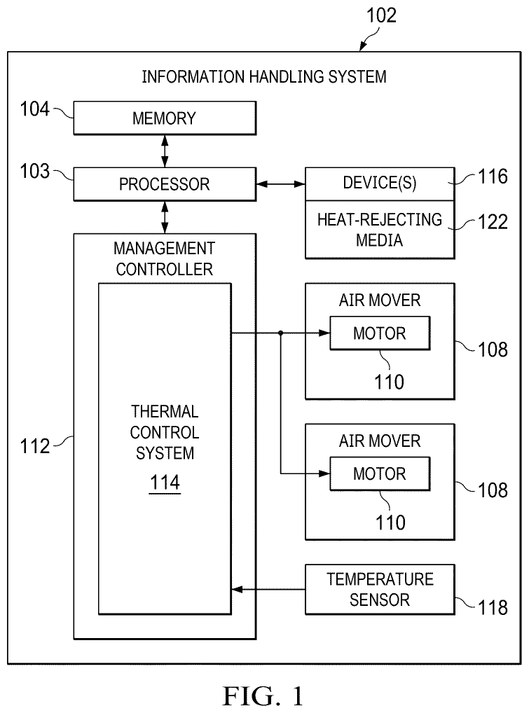

Preferred embodiments and their advantages are best understood by reference to FIGS. 1 through 4, wherein like numbers are used to indicate like and corresponding parts.

For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a PDA, a consumer electronic device, a network storage device, or any other suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include any instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory; as well as communications media such as wires, optical fibers, microwaves, radio waves, and other electromagnetic and/or optical carriers; and/or any combination of the foregoing.

For the purposes of this disclosure, information handling resources may broadly refer to any component system, device or apparatus of an information handling system, including without limitation processors, buses, memories, I/O devices and/or interfaces, storage resources, network interfaces, motherboards, integrated circuit packages; electro-mechanical devices (e.g., air movers), displays, and power supplies.

For the purposes of this disclosure, circuit boards may broadly refer to printed circuit boards (PCBs), printed wiring boards (PWBs), printed wiring assemblies (PWAs), etched wiring boards, and/or any other board or similar physical structure operable to mechanically support and electrically couple electronic components (e.g., packaged integrated circuits, slot connectors, etc.). A circuit board may comprise a substrate of a plurality of conductive layers separated and supported by layers of insulating material laminated together, with conductive traces disposed on and/or in any of such conductive layers, with vias for coupling conductive traces of different layers together, and with pads for coupling electronic components (e.g., packaged integrated circuits, slot connectors, etc.) to conductive traces of the circuit board.

FIG. 1 illustrates a block diagram of selected components of an example information handling system 102, in accordance with embodiments of the present disclosure. In some embodiments, information handling system 102 may comprise a server chassis configured to house a plurality of servers or “blades. ” In other embodiments, information handling system 102 may comprise a personal computer (e.g., a desktop computer, laptop computer, mobile computer, and/or notebook computer). In yet other embodiments, information handling system 102 may comprise a storage enclosure configured to house a plurality of physical disk drives and/or other computer-readable media for storing data. As shown in FIG. 1, information handling system 102 may comprise a processor 103, a memory 104 communicatively coupled to processor 103, a plurality of air movers 108, a management controller 112, one or more devices 116 communicatively coupled to processor 103, a temperature sensor 118, and heat-rejecting media 122 thermally coupled to device(s) 116.

Processor 103 may comprise any system, device, or apparatus operable to interpret and/or execute program instructions and/or process data, and may include, without limitation a microprocessor, microcontroller, digital signal processor (DSP), application specific integrated circuit (ASIC), or any other digital or analog circuitry configured to interpret and/or execute program instructions and/or process data. In some embodiments, processor 103 may interpret and/or execute program instructions and/or process data stored in memory 104 and/or another component of information handling system 102.

Memory 104 may be communicatively coupled to processor 103 and may comprise any system, device, or apparatus operable to retain program instructions or data for a period of time. Memory 104 may comprise random access memory (RAM), electrically erasable programmable read-only memory (EEPROM), a PCMCIA card, flash memory, magnetic storage, opto-magnetic storage, or any suitable selection and/or array of volatile or non-volatile memory that retains data after power to information handling system 102 is turned off.

An air mover 108 may include any mechanical or electro-mechanical system, apparatus, or device operable to move air and/or other gases in order to cool information handling resources of information handling system 102. In some embodiments, an air mover 108 may comprise a fan (e.g., a rotating arrangement of vanes or blades which act on the air). In other embodiments, an air mover 108 may comprise a blower (e.g., a centrifugal fan that employs rotating impellers to accelerate air received at its intake and change the direction of the airflow). In these and other embodiments, rotating and other moving components of an air mover 108 may be driven by a motor 110. The rotational speed of motor 110 may be controlled by an air mover control signal (e.g., a pulse-width modulation signal) communicated from thermal control system 114 of management controller 112. In operation, an air mover 108 may cool information handling resources of information handling system 102 by drawing cool air into an enclosure housing the information handling resources from outside the chassis, expelling warm air from inside the enclosure to the outside of such enclosure, and/or moving air across one or more heat sinks (not explicitly shown) internal to the enclosure to cool one or more information handling resources.

Management controller 112 may comprise any system, device, or apparatus configured to facilitate management and/or control of information handling system 102 and/or one or more of its component information handling resources. Management controller 112 may be configured to issue commands and/or other signals to manage and/or control information handling system 102 and/or its information handling resources. Management controller 112 may comprise a microprocessor, microcontroller, DSP, ASIC, field programmable gate array (“FPGA”), EEPROM, or any combination thereof. Management controller 112 also may be configured to provide out-of-band management facilities for management of information handling system 102. Such management may be made by management controller 112 even if information handling system 102 is powered off or powered to a standby state. In certain embodiments, management controller 112 may include or may be an integral part of a baseboard management controller (BMC), a remote access controller (e.g., a Dell Remote Access Controller or Integrated Dell Remote Access Controller), or an enclosure controller. In other embodiments, management controller 112 may include or may be an integral part of a chassis management controller (CMC).

As shown in FIG. 1, management controller 112 may include a thermal control system 114. Thermal control system 114 may include any system, device, or apparatus configured to receive one or more signals indicative of one or more temperatures within information handling system 102 (e.g., one or more signals from one or more temperature sensors 118) and based on such one or more signals, calculate an air mover driving signal (e.g., a pulse-width modulation signal) to maintain an appropriate level of cooling, increase cooling, or decrease cooling, as appropriate, and communicate such air mover driving signal to air movers 108. Thermal control for air movers 108 by thermal control system 114 may be performed in any suitable manner, for example, as described in U.S. Pat. No. 10,146,190 entitled “Systems and Methods for Providing Controller Response Stability in a Closed-Loop System. ” In addition, thermal control system 114 may also be configured to maintain acoustic limits and/or maintain acoustic preferences for sound generated by air movers 108, for example, as described in U.S. patent application Ser. No. 16/852,118, filed Apr. 17, 2020, and entitled “Systems and Methods for Acoustic Limits of Thermal Control System in an Information Handling System,” which is incorporated by reference herein in its entirety.

In some embodiments, thermal control system 114 may include a program of instructions (e.g., software, firmware) configured to, when executed by a processor or controller integral to management controller 112, carry out the functionality of thermal control system 114.

A device 116 may comprise any component information handling system of information handling system 102, including without limitation processors, buses, memories, I/O devices and/or interfaces, storage resources, network interfaces, motherboards, integrated circuit packages; electro-mechanical devices, displays, and power supplies.

Temperature sensor 118 may comprise any system, device, or apparatus (e.g., a thermometer, thermistor, etc.) configured to communicate a signal to thermal control system 114 indicative of a temperature within information handling system 102.

Heat-rejecting media 122 may include any system, device, or apparatus configured to transfer heat from an information handling resource (e.g., device(s) 116, as shown in FIG. 1), thus reducing a temperature of the information handling resource. For example, heat-rejecting media 122 may include one or more solids thermally coupled to the information handling resource (e.g., heat pipe, heat spreader, heatsink, vapor chamber, finstack, etc.) such that heat generated by the information handling resource is transferred from the information handling resource.

Further, heat-rejecting media 122 may be arranged to be located within the airflow path of airflow generated by air movers 108, such that heat transferred to heat-rejecting media 122 from device 116 may further be transferred to such airflow. Although, for purposes of clarity and exposition, heat-rejecting media 122 is shown as being thermally coupled to device(s) 116, it is understood that heat-rejecting media 122 may also be thermally coupled to other information handling resources (e.g., processor 103 and/or memory 104) of information handling system 102 in addition to or in lieu of being thermally coupled to device 116.

In addition to processor 103, memory 104, air mover 108, management controller 112, device(s) 116, temperature sensor 118, and heat-rejecting media 122, information handling system 102 may include one or more other information handling resources. In addition, for the sake of clarity and exposition of the present disclosure, FIG. 1 depicts two air movers 108 and one temperature sensor 118. In embodiments of the present disclosure, information handling system 102 may include any number of air movers 108 and temperature sensors 118.

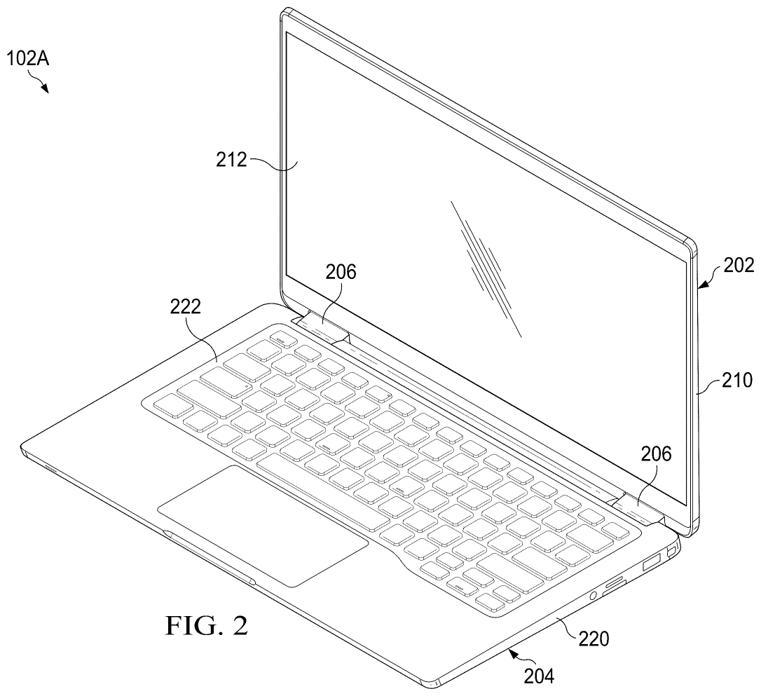

FIG. 2 illustrates selected components of an example notebook 102A, in accordance with embodiments of the present disclosure. Notebook 102A may implement information handling system 102. As shown in FIG. 2, notebook 102A may include a display assembly 202 and a keyboard assembly 204 rotatably coupled to one another via one or more hinges 206. Display assembly 202 may comprise a housing 210 that may house components of notebook 102A including a display device 212 (e.g., liquid-crystal display) for outputting alphanumeric and/or graphical output. Keyboard assembly 204 may comprise a housing 220 that may house components of notebook 102A including a keyboard 222 for inputting information to notebook 102A. Keyboard assembly 204 may also include other components of information handling system 102 (e.g., processor 103, memory 104, management controller 112, device(s) 116, air movers 108, temperature sensor 118, heat-rejecting media 122, etc.) not explicitly depicted in FIG. 2.

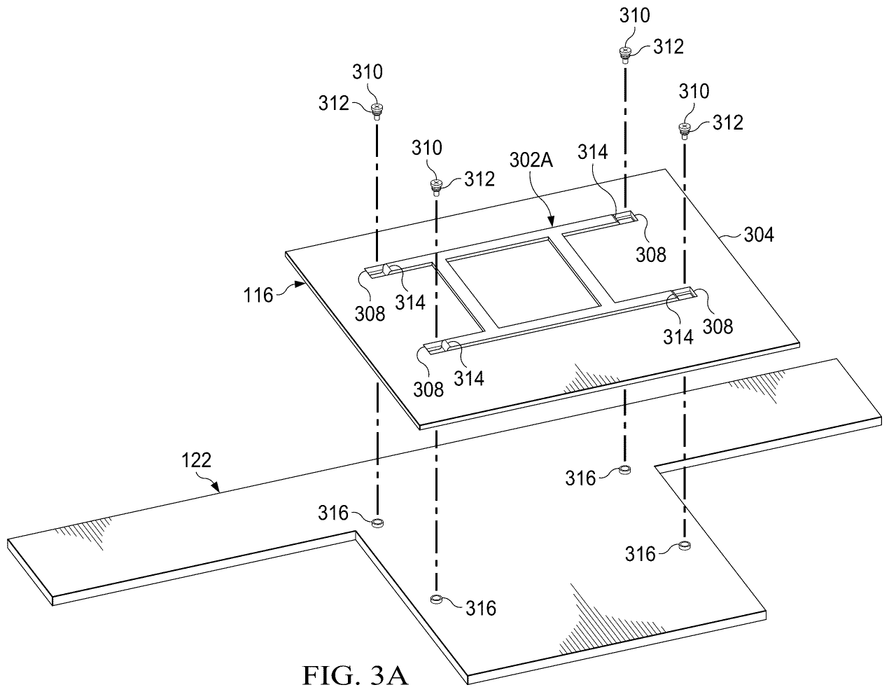

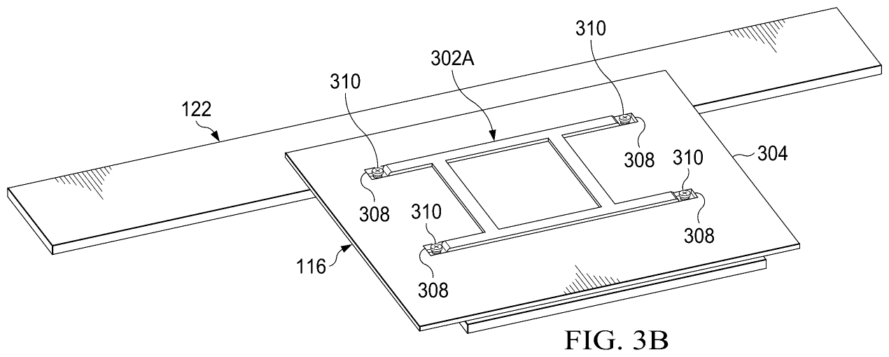

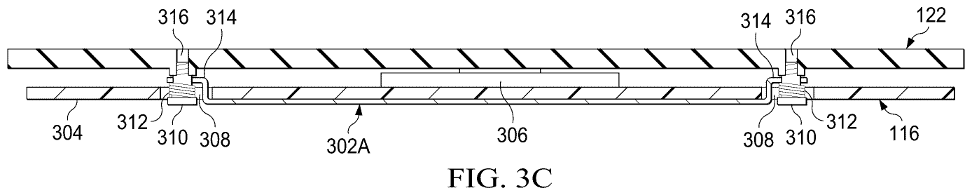

FIG. 3A illustrates an exploded isometric perspective view of selected components of notebook 102A depicted in FIG. 2, demonstrating a system and method for board-side mounting of a device 116 to heat-rejecting media 122 using a bracket 302A with drop-down ends 314, in accordance with embodiments of the present disclosure. FIG. 3B illustrates an assembled isometric perspective view of the selected components depicted in FIG. 3A, in accordance with embodiments of the present disclosure, while FIG. 3C illustrates an assembled cross-sectional elevation perspective view of the selected components depicted in FIGS. 3A and 3B, in accordance with embodiments of the present disclosure.

As shown in FIGS. 3A-3C, device 116 may be implemented with a circuit board 304 having an integrated circuit chip 306 mounted to a first surface of circuit board 304. Also as shown in FIGS. 3A-3C, bracket 302A may be mounted to a second surface of circuit board 304 opposite of the first surface. In some embodiments, bracket 302A may be mounted to the second surface of circuit board 304 directly opposite of where integrated circuit chip 306 is mounted to the first surface. Further, circuit board 304 may include a plurality of openings 308 formed in the second surface. In some embodiments, openings 308 may be formed completely through circuit board 304 (i.e., through the first surface and the second surface).

Bracket 302A may comprise any suitable mechanical component configured to, when mechanically coupled to heat-rejecting media 122 as described in greater detail below, apply mechanical pressure between integrated circuit chip 306 and heat-rejecting media 122 in order to thermally couple integrated circuit chip 306 and heat-rejecting media 122. As shown in FIGS. 3A-3C, when bracket 302A is mounted upon circuit board 304, a plurality of ends 314 of bracket 302A may pass into (and in some embodiments, through) openings 308.

In addition, each end 314 of bracket 302A may have mechanical features (e.g., openings, not explicitly shown) configured to receive a corresponding mechanical screw 310 therethrough. As also shown in FIGS. 3A-3C, each mechanical screw 310 may have a corresponding coil spring 312 wrapped around at least a portion of the length of such mechanical screw 310.

Further, heat-rejecting media 122 may include a plurality of threaded inserts 316, wherein each mechanical screw 310 may pass into (and in some embodiments, through) a respective opening 308, through a respective mechanical feature formed in a respective end 314, and into a respective threaded insert 316. With the plurality of mechanical screws 310 mechanically engaged with the plurality of threaded inserts 316, coil springs 312 may exert a spring force that applies mechanical pressure between integrated circuit chip 306 and heat-rejecting media 122, thus thermally coupling integrated circuit chip 306 and heat-rejecting media 122. In some embodiments, once each mechanical screw 310 is fully mechanically engaged with its respective threaded insert 314, the height of each mechanical screw 310 in a direction parallel to the axes of each mechanical screw 310 may be less than or equal to the combined height of device 116 and heat-rejecting media 122 in the same direction.

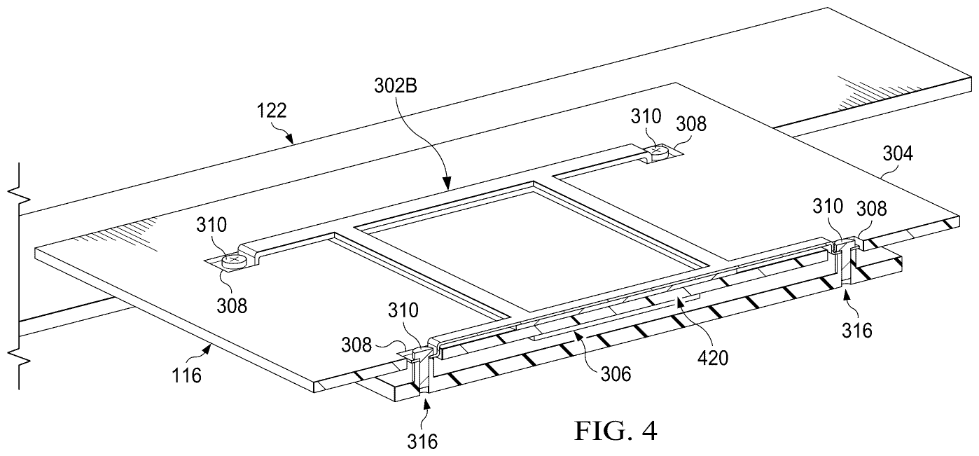

FIG. 4 illustrates an assembled isometric perspective view of selected components of the notebook 102A depicted in FIG. 3, demonstrating another system and method for board-side mounting of device 116 to heat-rejecting media 122 using a bracket 302B with drop-down ends 314, in accordance with embodiments of the present disclosure. The components shown in FIG. 4 are similar in many respects to the components shown in FIGS. 3A-3C, and thus, only certain differences between FIGS. 3A-3C and FIG. 4 are described below. In particular, FIG. 4 may include bracket 302B in lieu of bracket 302A of FIGS. 3A-3C, may include stiffener plate 420 not present in FIGS. 3A-3C, and may exclude coil springs 312 present in FIGS. 3A-3C. Further, bracket 302B may be a leaf spring configured to exert a spring force to apply mechanical pressure between integrated circuit chip 306 and heat-rejecting media 122, thus thermally coupling integrated circuit chip 306 and heat-rejecting media 122 when mechanical screws 310 are fully engaged with threaded inserts 316, thus thermally coupling integrated circuit chip 306 and heat-rejecting media 122. Because bracket 302B comprises a leaf spring and may provide adequate spring force, screws 310 may not include coil springs 312.

Stiffener plate 420 may comprise an optional component that may not be present in all implementations. When present, stiffener plate 420 may apply mechanical stiffness to circuit board 304 to further aid in the application of mechanical pressure between integrated circuit chip 306 and heat-rejecting media 122.

Although FIGS. 3A-3C and 4 depict device 116 mechanically and thermally coupled to heat-rejecting media 122, it is understood that in some embodiments, processor 103 may be mounted to a circuit board and mechanically and thermally coupled to heat-rejecting media 122 in a manner similar to that described above. Furthermore, in some embodiments, device 116 may include a graphics processing unit.

The various components shown in FIGS. 3A-3C and 4 may be located internally to a housing of an information handling system 102 or notebook 102A. For example, components shown in FIGS. 3A-3C and 4 may be present within housing 220 of keyboard assembly 204.

While the terms “top,” “bottom,” “front,” “back,” and “side” are used for purposes of exposition and clarity, such terms are not intended to limit any of the components disclosed herein to a particular orientation or configuration.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. An information handling system comprising:
a circuit board comprising:
an electronic device mechanically and electrically mounted on a first surface of the circuit board;
a plurality of openings formed within a second surface of the circuit board opposite of the first surface; and
a bracket mechanically mounted to the second surface, the bracket comprising a plurality of ends, each end extending into a respective opening of the plurality of openings;
heat-rejecting media; and
a plurality of mechanical fastening devices, each mechanical fastening device mechanically engaged with a respective first mechanical feature formed in a respective end of the plurality of ends and mechanically engaged with a respective second mechanical feature formed in the heat-rejecting media in order to apply a spring force between the bracket and the heat-rejecting media that applies mechanical pressure to thermally couple the electronic device to the heat-rejecting media.

2. The information handling system of claim 1, wherein:
the plurality of openings are formed through the second surface and the first surface; and
the plurality of ends pass entirely through the plurality of openings.

3. The information handling system of claim 1, wherein the bracket is mounted to the second surface directly opposite of where the electronic device is mounted to the first surface.

4. The information handling system of claim 1, wherein the bracket comprises a leaf spring configured to apply the spring force.

5. The information handling system of claim 1, wherein each mechanical fastening device comprises a respective coil spring wrapped around such mechanical fastening device and configured to apply the spring force.

6. The information handling system of claim 1, the circuit board further comprising a mechanical stiffener plate interfaced between the bracket and the second surface.

7. The information handling system of claim 1, wherein a combined height of each mechanical fastening device and respective second mechanical feature in a direction parallel to an axis of such mechanical device is less than or equal to a combined height of the circuit board, electronic device, and heat-rejecting media.

8. The information handing system of claim 1, wherein the electronic device comprises a processor.

9. The information handing system of claim 1, wherein the electronic device comprises a graphics processing unit.

10. The information handling system of claim 1, wherein the heat-rejecting media comprises at least one of a heat pipe, a heat spreader, a heatsink, a vapor chamber, a fin stack.

11. A method comprising:
mechanically engaging each of a plurality of mechanical fastening devices with a respective first mechanical feature; and
mechanically engaging each of the plurality of mechanical fastening devices with a respective second mechanical feature formed in the heat-rejecting media;
wherein:
each of the first mechanical features are formed in a respective end of a bracket mounted to a first surface of a circuit board and each of the first mechanical features extend into a respective opening of a plurality of openings formed within a first surface of the circuit board; and
the circuit board comprises an electronic device mechanically and electrically mounted on a second surface of the circuit board opposite of the first surface;
such that a spring force is applied between the bracket and the heat-rejecting media that applies mechanical pressure to thermally couple the electronic device to the heat-rejecting media.

12. The method of claim 11, wherein:
the plurality of openings are formed through the second surface and the first surface; and
the plurality of ends pass entirely through the plurality of openings.

13. The method of claim 11, wherein the bracket is mounted to the second surface directly opposite of where the electronic device is mounted to the first surface.

14. The method of claim 11, wherein the bracket comprises a leaf spring configured to apply the spring force.

15. The method of claim 11, wherein each mechanical fastening device comprises a respective coil spring wrapped around such mechanical fastening device and configured to apply the spring force.

16. The method of claim 11, wherein the circuit board further comprises a mechanical stiffener plate interfaced between the bracket and the first surface.

17. The method of claim 11, wherein a combined height of each mechanical fastening device and respective second mechanical feature in a direction parallel to an axis of such mechanical device is less than or equal to a combined height of the circuit board, electronic device, and heat-rejecting media.

18. The method of claim 11, wherein the electronic device comprises a processor.

19. The method of claim 11, wherein the electronic device comprises a graphics processing unit.

20. The method of claim 11, wherein the heat-rejecting media comprises at least one of a heat pipe, a heat spreader, a heatsink, a vapor chamber, a fin stack.
